(19) United States
(12) Patent Application Publication
(10) Pub. No.: US 2007/0241345 A1
(43) Pub. Date: Oct. 18, 2007

(54) Semiconductor light-emitting device and method of fabricating the same

(75) Inventor: Kuo-Hsin Huang, Hsinchu (TW)

Correspondence Address: BIRCH STEWART KOLASCH & BIRCH, PO BOX 747, FALLS CHURCH, VA, 22040-0747, US

(73) Assignee: HIGH POWER OPTOELECTRONICS, INC.

(21) Appl. No.: 11/785,024

(22) Filed: Apr. 13, 2007

(30) Foreign Application Priority Data
Apr. 14, 2006 (TW) 095113266

(51) Int. Cl. H01L 33/00; H01L 23/48; H01L 31/12; H01L 21/00

(52) U.S. Cl. 257/79; 257/734; 438/22

(57) ABSTRACT

The present invention provides a semiconductor light emitting device which includes a multi-layer structure. Additionally, an electrode is disposed on a first surface of the multi-layer structure. Furthermore, the electrode includes a plurality of bonding pads.

### BACKGROUND OF THE INVENTION

1. Field of the Invention

The present invention is related to a semiconductor device and the method of fabricating the same, and more particularly, to a semiconductor light-emitting device and the method of fabricating the same.

2. Description of the Prior Art

Because of the advantages of long life span, light weight, low power consumption, and absence of mercury semiconductor light-emitting device, such as light-emitting diode (LED), has become an ideal light source, and it has been greatly developed. LED can be applied in many fields, including information, communication, consumer electronics, vehicles, traffic light, billboard, and illumination market. The most popular fields include the communication industry, such as in the back light of cellular phones and the light of keypads; the vehicle industry, such as the signal lights and the dashboards of cars; and other illumination industries, such as in billboards and lightings.

Referring to FIG. 1A and FIG. 1B, FIG. 1A is a side view of a semiconductor light-emitting device of the prior art, whereas FIG. 1B is a top view of the semiconductor light-emitting device of FIG. 1A. As shown in FIG. 1A and FIG. 1B, the semiconductor light-emitting device 5 includes a multi-layer structure 51 and an electrode 53, such as a p-type electrode, which is disposed on a surface of the multi-layer structure. Moreover, the electrode 53 is electrically connected to a respective external power source (not shown) through a wire 55.

Because the semiconductor light-emitting device of the prior art only has a p-type electrode or an n-type electrode, and each of the electrodes is electrically connected to a respective external power source through only one wire, it has the advantage of low cost. However, when the electric current exceeds the load of the electrode or the wire, or other reasons cause the break down of the electrode or the wire, the semiconductor light-emitting device will lose its function and fail to illuminate.

Recently, the requirement of the quality of semiconductor light-emitting devices is higher in several applying fields, such as in the back light of televisions or monitor screens. Therefore, it is necessary to fabricate semiconductor light-emitting device with higher stability.

### SUMMARY OF THE INVENTION

Accordingly, a scope of the invention is to provide a semiconductor light-emitting device, which is more stable than the prior art as described above. Moreover, the semiconductor light-emitting device of the present invention will not easily break down, so it can improve the disadvantages of the prior art described above.

According to a preferred embodiment of the present invention, the semiconductor light-emitting device includes a multi-layer structure. Moreover, an electrode is disposed on a surface of the multi-layer structure. Furthermore, the electrode includes a plurality of bonding pads.

According to another preferred embodiment of the present invention, the semiconductor light-emitting device includes a substrate, a semiconductor multi-layer structure, and a plurality of wires. The semiconductor multi-layer structure is disposed on the substrate, whereas an electrode is disposed on a surface of the semiconductor multi-layer structure. Furthermore, the plurality of wires is connected to the electrode.

In addition, another scope of the present invention is to provide a method of fabricating a semiconductor light-emitting device. Furthermore, the semiconductor light-emitting device produced by this method has higher quality.

According to a preferred embodiment of the present invention, the method for fabricating a semiconductor light-emitting device includes steps as follows: first of all, a substrate is prepared. Afterward, a semiconductor multi-layer structure is formed over the substrate. Finally, an electrode, including a plurality of bonding pads, is disposed on a surface of the semiconductor multi-layer structure.

The scope of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1A and FIG. 1B are schematic diagrams of semiconductor light-emitting device of the prior art.

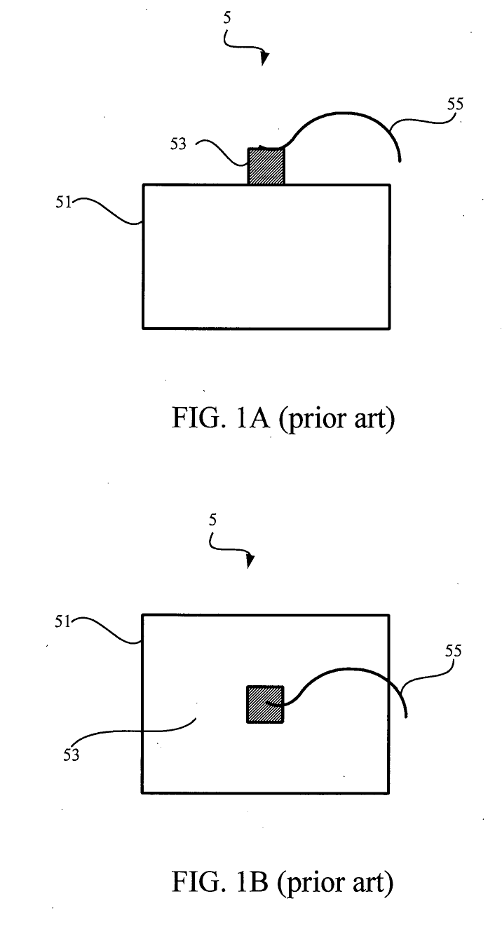

FIG. 2 is a top view of a semiconductor light-emitting device according to an embodiment of the present invention.

FIG. 3A and FIG. 3B are top views of semiconductor light-emitting devices according to an embodiment of the present invention.

FIG. 4 is a top view of a semiconductor light-emitting device according to an embodiment of the present invention.

FIG. 5 is a top view of a semiconductor light-emitting device according to a preferred embodiment of the present invention.

FIG. 6 illustrates a flow chart of a method of fabricating a semiconductor light-emitting device according to an embodiment of the present invention.

### DETAILED DESCRIPTION OF THE INVENTION

The present invention is to provide a semiconductor light-emitting device. The preferred embodiments are disclosed as below.

In a preferred embodiment of the invention, the semiconductor light-emitting device includes a multi-layer structure. In addition, an electrode is disposed on a surface of the multi-layer structure, and it includes a plurality of bonding pads. In practice, the electrode can be a p-type electrode or an n-type electrode.

In practice, the multi-layer structure can further includes a substrate layer, a light-emitting layer, and a reflecting layer. In practice, the multi-layer structure can further includes other layers with different material or different functions if necessary.

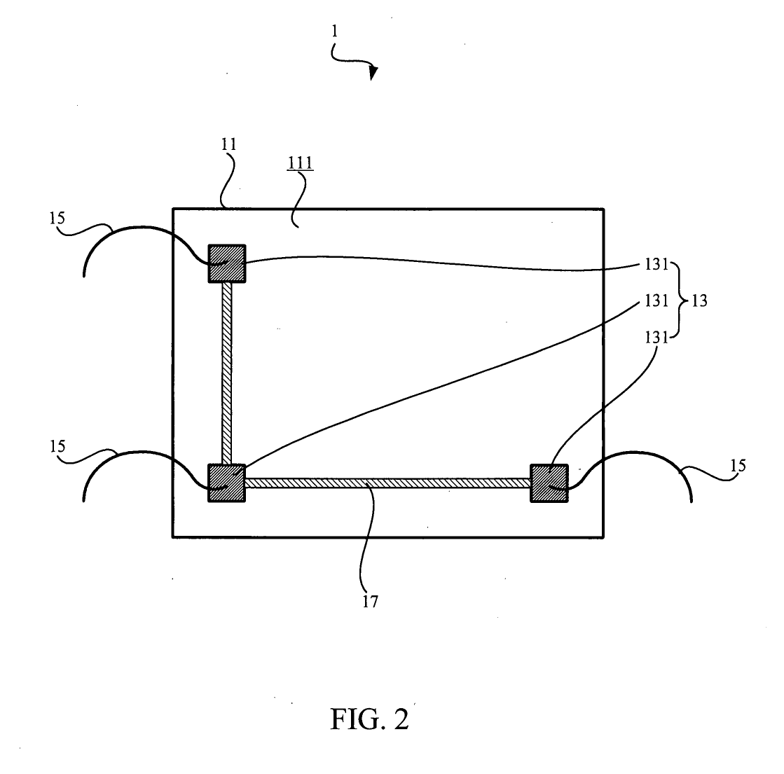

Referring to FIG. 2, FIG. 2 is a top view of a semiconductor light-emitting device according to an embodiment of the present invention. As shown in FIG. 2, the semiconductor light-emitting device 1 includes a multi-layer structure 11. Furthermore, an electrode 13 is disposed on a surface 111 of the multi-layer structure 11; the electrode 13 also includes 3 bonding pads 131. As shown in FIG. 2, the semiconductor light-emitting device 1 also includes a plurality of wires 15, each connected to the three bonding pads 131 respectively. The plurality of wires 15 is capable of electrically connecting the three bonding pads 131 to an external power source (not shown).

As shown in FIG. 2, the plurality of bonding pads 131 are electrically connected with each other through a metal conductor 17. Furthermore, the plurality of bonding pads 131 can be electrically connected with each other through other conductors, such as semiconductor (e.g. the semiconductor multi-layer structure itself).

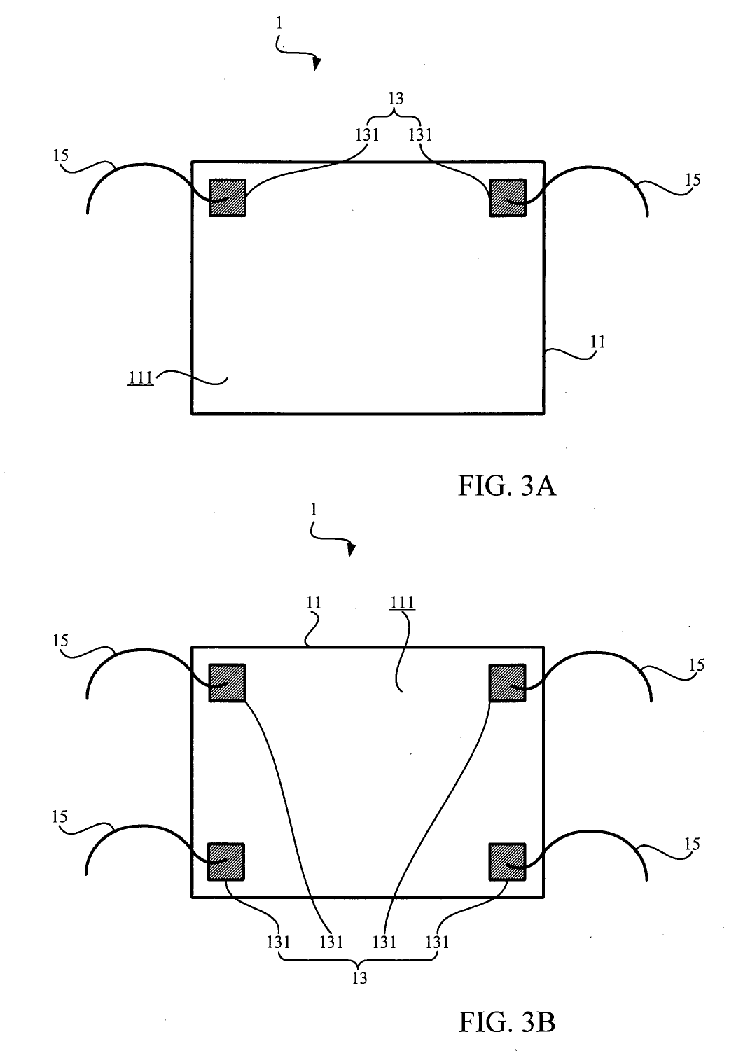

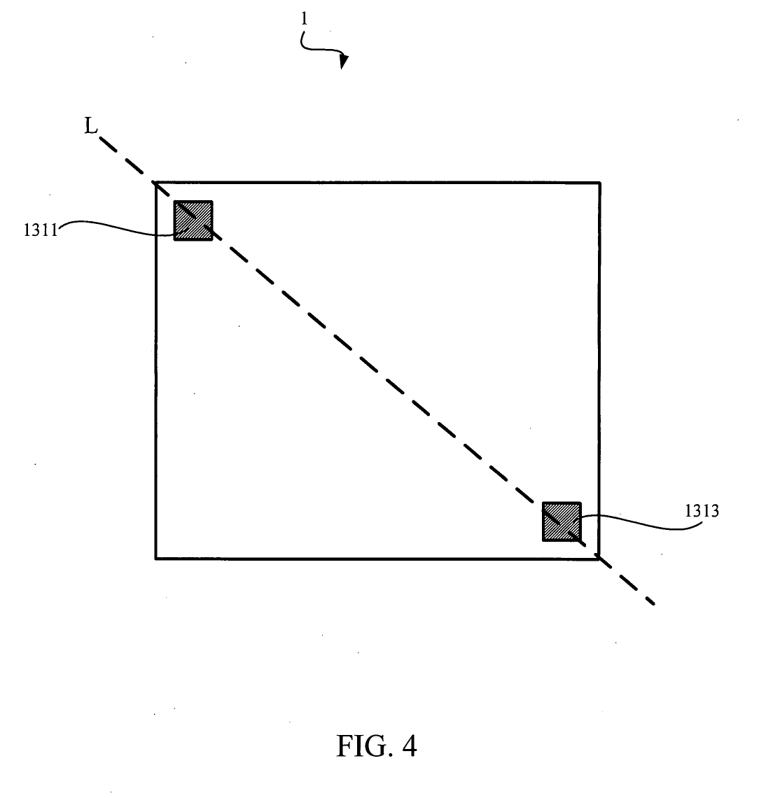

Furthermore, as shown in FIG. 3A and FIG. 3B, the semiconductor light-emitting devices, according to the present invention, can include two bonding pads 131 (as shown in FIG. 3A) or 4 bonding pads 131 (as shown in FIG. 3B). It should be noted that the semiconductor light-emitting device of the present invention can include other number of bonding pads if necessary.

Referring to FIG. 4, FIG. 4 is a top view of a semiconductor light-emitting device according to an embodiment of the present invention. In the embodiment, the plurality of bonding pads includes a first bonding pad 1311 and a second bonding pad 1313. More particularly, the first bonding pad 1311 and the second bonding pad 1313 are disposed on a diagonal line L of the surface. In practice, the area of each of the plurality of bonding pads is in the range of 1% to 25% of the area of the surface, such as 2%.

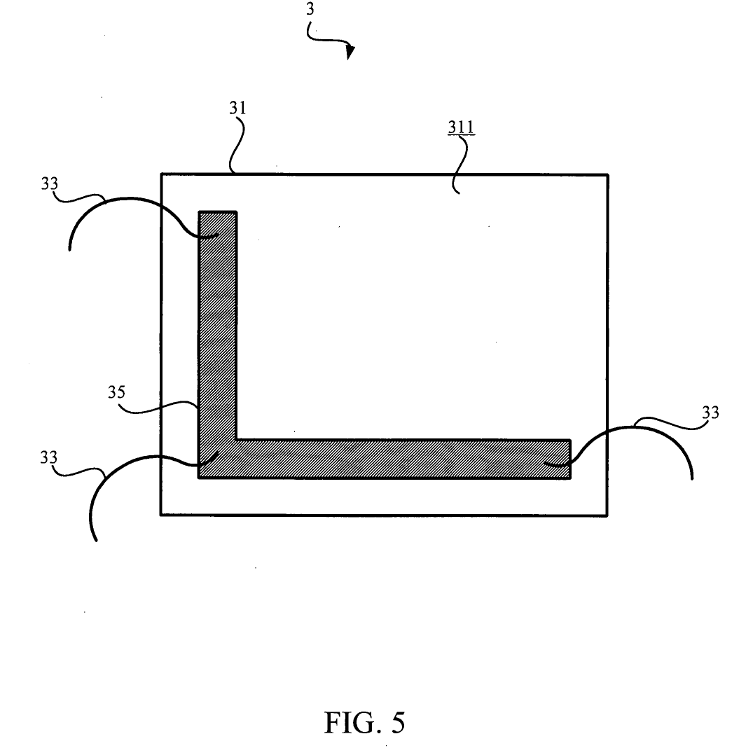

Please refer to FIG. 5, which shows a top view of a semiconductor light-emitting device according to a preferred embodiment of the present invention. In the preferred embodiment, a semiconductor light-emitting device 3, in accordance with the invention, includes a substrate (not shown), a semiconductor multi-layer structure 31, and a plurality of wires 33. The semiconductor multi-layer structure 31 is disposed over the substrate, and an electrode 35 is disposed on a surface 311 of the multi-layer structure 31. Furthermore, the plurality of wires 33 is electrically connected to the electrode 35. In practice, the electrode 35 can be a p-type electrode or an n-type electrode.

In an embodiment of the invention, the plurality of wires includes a first wire and a second wire. Particularly, the contact of the first wire and the second wire with the electrode are disposed on a diagonal line of the surface.

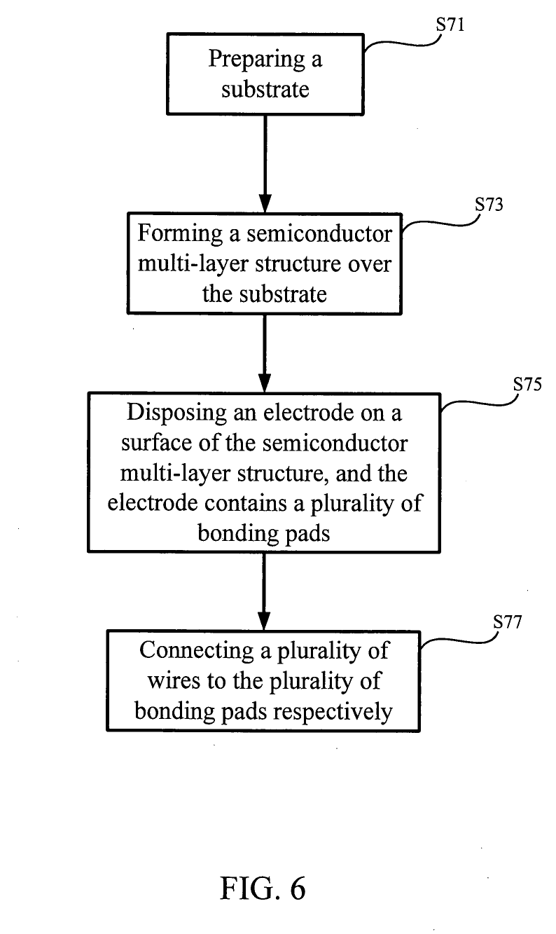

In an embodiment of the present invention, a method of fabricating a semiconductor light-emitting device is provided. Please refer to FIG. 6; as shown in FIG. 6, the method includes 4 steps: first, a substrate is prepared (S71). Afterward, a semiconductor multi-layer structure is formed over the substrate (S73). Then, an electrode is disposed on a surface of the semiconductor multi-layer structure, and the electrode includes a plurality of bonding pads. Finally, a plurality of wires are respectively connected to the plurality of corresponding bonding pads (S77).

In practice, the area of each the plurality of bonding pads is in the range of 1% to 25% of the area of the surface. In practical application, the plurality of bonding pads further includes a first bonding pad and a second bonding pad. More particularly, the first bonding pad and the second bonding pad are disposed on a diagonal line of the surface.

Obviously, the semiconductor light-emitting device of the present invention has a plurality of bonding pads or wires. Therefore, even some of the bonding pads or wires are broken down, the semiconductor light-emitting device can maintain its function through other wires and/or bonding pads. Accordingly, the semiconductor light-emitting device of the invention is more stable than those of the prior art, and it does not easily break down during uses thereof. Furthermore, because the bonding pads are disposed at the edge of the surface of the semiconductor light-emitting device of the invention, the light path of the semiconductor light-emitting device will not be blocked, and the situation of insufficient brightness or hollowness in the central part of light can be avoided.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor light-emitting device, comprising a multi-layer structure, wherein an electrode is disposed on a surface of the multi-layer structure, and the electrode comprising a plurality of bonding pad.

2. The semiconductor light-emitting device of claim 1, wherein the electrode is a p-type electrode.

3. The semiconductor light-emitting device of claim 1, wherein the electrode is an n-type electrode.

4. The semiconductor light-emitting device of claim 1, wherein the plurality of bonding pads are electrically connected with each other through a conductor.

5. The semiconductor light-emitting device of claim 4, wherein the conductor is a metal.

6. The semiconductor light-emitting device of claim 4, wherein the conductor is a semiconductor.

7. The semiconductor light-emitting device of claim 1, wherein the area of each the plurality of bonding pads is in the range of 1% to 25% of the area of the surface.

8. The semiconductor light-emitting device of claim 1, wherein the plurality of bonding pads further includes a first bonding pad and a second bonding pad, and the first bonding pad and the second bonding pad are disposed on a diagonal of the surface.

9. The semiconductor light-emitting device of claim 1, further comprising a plurality of wires connecting to the plurality of bonding pads respectively.

10. A semiconductor light-emitting device, comprising:
a substrate;
a multi-layer structure, disposing over the substrate, and an electrode disposing on a surface of the multi-layer structure; and
a plurality of wires connecting to the electrode.

11. The semiconductor light-emitting device of claim 10, wherein the electrode is a p-type electrode.

12. The semiconductor light-emitting device of claim 10, wherein the electrode is an n-type electrode.

13. The semiconductor light-emitting device of claim 10, wherein the plurality of wires further includes a first wire and a second wire, and the first wire and the second wire are disposed on a diagonal of the surface.

14. A method of fabricating a semiconductor light-emitting device, the method comprising the steps of:
(a) preparing a substrate;
(b) forming a semiconductor multi-layer structure over the substrate; and
(c) disposing an electrode on a surface of the semiconductor multi-layer structure, and the electrode comprising a plurality of bonding pads.

15. The method of claim 14, further comprising the step of:
(d) connecting a plurality of wires to the plurality of bonding pads respectively.

16. The method of claim 14, wherein the area of each the plurality of bonding pads is in the range of 1% to 25% of the area of the surface.

17. The method of claim 14, wherein the plurality of bonding pads further includes a first bonding pad and a second bonding pad, and the first bonding pad and the second bonding pad are disposed on a diagonal of the surface.
